(19) United States
(12) Patent Application Publication
(10) Pub. No.: US 2014/0014175 A1
(43) Pub. Date: Jan. 16, 2014

(54) SOLAR CELL ELEMENT AND SOLAR CELL MODULE

(71) Applicants: Norikazu Ito, Moriyama-shi (JP); Akira Murao, Moriyama-shi (JP); Makoto Onodera, Ritto-shi (JP); Takeshi Ito, Higashiomi-shi (JP); Shinichiro Inaba, Gamo-gun (JP)

(72) Inventors: Norikazu Ito, Moriyama-shi (JP); Akira Murao, Moriyama-shi (JP); Makoto Onodera, Ritto-shi (JP); Takeshi Ito, Higashiomi-shi (JP); Shinichiro Inaba, Gamo-gun (JP)

(73) Assignee: KYOCERA CORPORATION, Kyoto-shi, Kyoto (JP)

(21) Appl. No.: 14/008,807

(22) PCT Filed: Mar. 29, 2012
(86) PCT No.: PCT/JP2012/058447

§ 371 Date: Sep. 30, 2013

(30) Foreign Application Priority Data
Mar. 31, 2011 (JP) 2011-077382

(51) Int. Cl. H01L 31/0216

(52) U.S. Cl. CPC H01L 31/02167
USPC 136/256

(57) ABSTRACT

A solar cell element and a solar cell module are disclosed. The solar cell element includes a polycrystalline silicon substrate and an aluminum oxide layer on the p-type semiconductor layer. The polycrystalline silicon substrate includes a p-type semiconductor layer located at the uppermost position. The aluminum oxide layer is primarily amorphous. The solar cell module includes the above-mentioned solar cell element.

### FIELD OF ART

The present invention relates to a solar cell element and a solar cell module including the same.

### BACKGROUND ART

In a solar cell element including a silicon substrate, a passivation film is provided on a surface of the silicon substrate in order to reduce recombination of minority carriers. As this passivation film, the use of an oxidation film made from silicon oxide, aluminum oxide, or the like, or a nitride film made from a silicon nitride film, or the like, has been studied (for example, see Japanese Unexamined Patent Application Publication No. 2009-164544).

### SUMMARY OF THE INVENTION

### Problem to be Solved by the Invention

However, in a related solar cell element, an improvement that only contributes to power generation efficiency may not be sufficiently satisfied in some cases. Hence, a solar cell element which reduces recombination of minority carriers as compared to that in the past and which further enhances an output performance and a solar cell module including the above solar cell element have been desired.

### Means for Solving the Problem

Hence, a solar cell element according to an embodiment of the present invention includes: a polycrystalline silicon substrate on which a p-type semiconductor layer is located at the uppermost position; and an aluminum oxide layer disposed on the p-type semiconductor layer, and the aluminum oxide layer is primarily amorphous.

Furthermore, a solar cell module according to another embodiment of the present invention includes the solar cell element described above.

### Effect of the Invention

According to the solar cell element and the solar cell module described above, a solar cell element and a solar cell module, each having a high open voltage and a good output performance, can be provided.

### BRIEF DESCRIPTION OF THE DRAWINGS

FIG. 1 is a schematic plan view showing an exemplary solar cell element according to an embodiment of the present invention, viewed from a first surface side.

FIG. 2 is a schematic plan view showing the exemplary solar cell element according to the embodiment of the present invention, viewed from a second surface side.

FIG. 3 is a schematic cross-sectional view showing the exemplary solar cell element according to the embodiment of the present invention taken along the line A-A in FIG. 1.

FIG. 4 is a schematic cross-sectional view showing the exemplary solar cell element according to an embodiment of the present invention taken along the line A-A in FIG. 1.

FIG. 5 is a schematic diagram showing an exemplary solar cell element according to an embodiment of the present invention, and FIGS. 5(a) and 5(b) are each a schematic plan view showing an exemplary solar cell element according to an embodiment of the present invention, viewed from a second surface side.

FIG. 6 is a schematic diagram illustrating an exemplary solar cell module according to an embodiment of the present invention, FIG. 6(a) is a partially enlarged cross-sectional view of the solar cell module, and FIG. 6(b) is a plan view of the solar cell module viewed from a first surface side.

FIG. 7 is a partially enlarged cross-sectional view schematically illustrating an exemplary solar cell module according to an embodiment of the present invention.

### EMBODIMENTS FOR CARRYING OUT THE INVENTION

Hereinafter, a solar cell element according to an embodiment of the present invention and a solar cell module including the solar cell element will be described in detail with reference to the drawings. Note that, in the drawings, portions having similar structures and functions are denoted by the same reference numeral, and a duplicated explanation will be omitted. In addition, since the drawings are schematically shown, the sizes of constituent members and the positional relationship therebetween are not always accurate.

### <Basic Structure of Solar Cell Element>

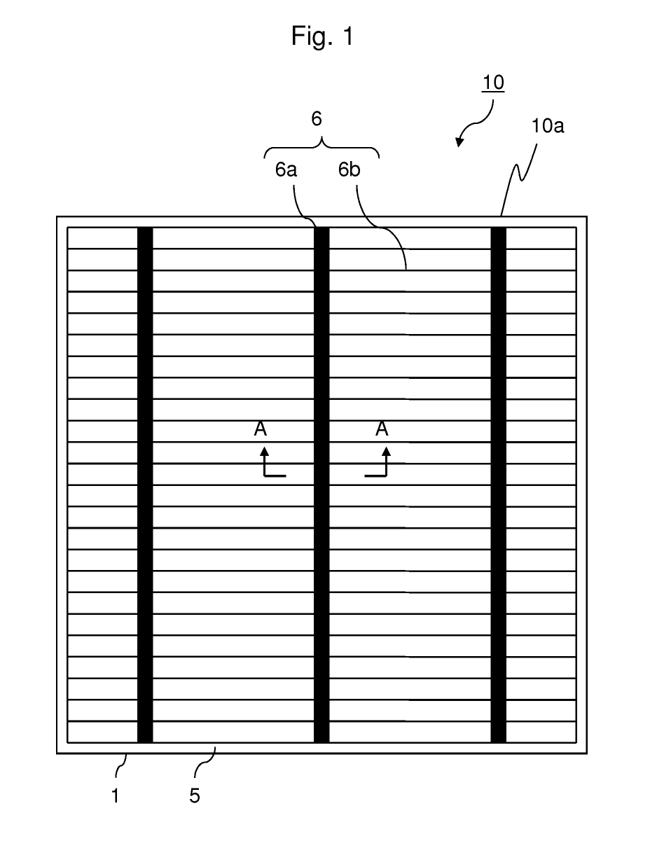

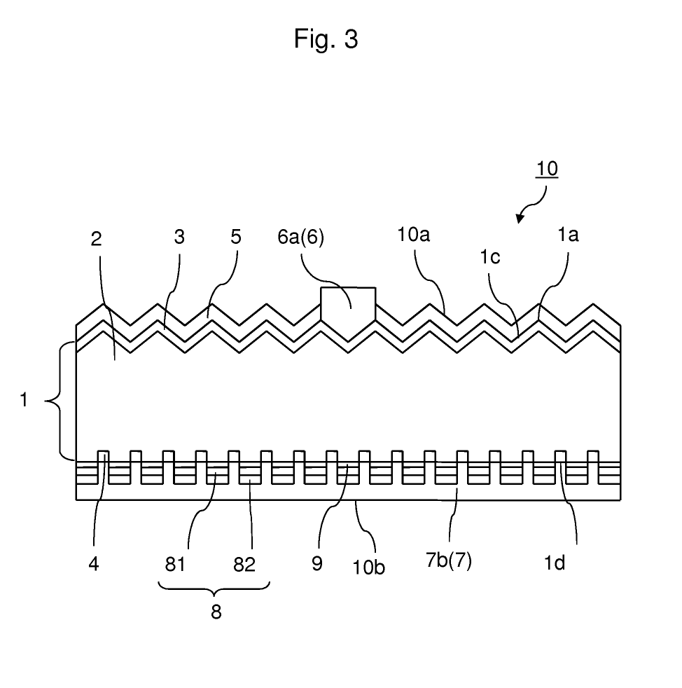

In FIGS. 1 to 3, a solar cell element 10 according to an embodiment of the present invention is entirely or partially shown. As shown in FIGS. 1 to 3, the solar cell element 10 includes a first surface 10a serving as a light receiving surface (upper surface in FIG. 3) on which light is incident and a second surface 10b serving as a non-light receiving surface (lower surface in FIG. 3) corresponding to a rear surface of the first surface 10a. In addition, the solar cell element 10 includes a semiconductor substrate 1 which is a polycrystalline silicon substrate having a plate shape.

As shown in FIG. 3, the semiconductor substrate 1 includes, for example, a first semiconductor layer (p-type semiconductor layer) 2 which is one conductive type semiconductor layer and a second semiconductor layer 3 which is an opposite conductive type semiconductor layer provided on the first semiconductor layer 2 at a first surface 10a side. In addition, a passivation layer 8 which is an aluminum oxide layer primarily as well as mainly a non-crystalline substance is disposed on the first semiconductor layer 2.

As described above, the solar cell element 10 comprises: the semiconductor substrate 1 which is a polycrystalline silicon substrate and which includes the first semiconductor layer 2 located at the uppermost position; and the passivation layer 8 which is disposed on the first semiconductor layer 2 and which primarily includes an amorphous aluminum oxide.

### <Specific Example of Solar Cell Element>

Next, a concrete example of the solar cell element according to an embodiment of the present invention will be described. As shown in FIG. 3, in the solar cell element 10, an anti-reflection layer 5 and a first electrode 6 are disposed on the semiconductor substrate 1 (the first semiconductor layer 2 and the second semiconductor layer 3) at the first surface 10a side, a third semiconductor layer 4 and the passivation layer 8 are disposed at a second surface 10b side of the first semiconductor layer 2, and a second electrode 7 is further disposed on those.

As described above, the semiconductor substrate 1 is a polycrystalline silicon substrate and includes the first semiconductor layer 2 and the second semiconductor layer 3 provided on the first semiconductor layer 2 at the first surface 10a side and having an opposite conductivity to that of the first semiconductor layer 2.

As described above, as the first semiconductor layer 2, a polycrystalline silicon substrate having a p-type conductivity can be used. The thickness of the first semiconductor layer 2 can be set, for example, to 250 μm or less or further set to 150 μm or less. Although the shape of the first semiconductor layer 2 is not particularly limited, from a manufacturing point of view, a square shape in plan view may be used. When the first semiconductor layer 2 is formed to have a p-type conductivity, as a dopant element, for example, boron or gallium may be used.

In this embodiment, the second semiconductor layer 3 is a semiconductor layer forming a pn junction with the first semiconductor layer 2. The second semiconductor layer 3 is a layer having an n-type conductivity which is opposite to that of the first semiconductor layer 2 and is provided on the first semiconductor layer 2 at the first surface 10a side. In a silicon substrate in which the first semiconductor layer 2 exhibits a p-type conductivity, for example, the second semiconductor layer 3 can be formed by diffusing an impurity, such as phosphorous, into the silicon substrate at the first surface 10a side.

As shown in FIG. 3, at a first primary surface 1c side functioning as a light receiving surface side of the semiconductor substrate 1, a first concavo-convex shape 1a is provided. The height of a convex portion of the first concavo-convex shape 1a is 0.1 to 10 μm, and the width of the convex portion is about 0.1 to 20 μm. The shape of the first concavo-convex shape 1a is not limited to a pyramid shape having an angular corner in cross-sectional view as shown in FIG. 3 and, for example, may be a concavo-convex shape having an about spherical concave portion.

Note that the “height of the convex portion” described above indicates a distance from a base line to the top surface of the convex portion in a direction perpendicular to the base line when the base line is defined as a line passing through bottom surfaces of the concave portions. In addition, the “width of the convex portion” described above indicates a distance between the top surfaces of adjacent convex portions in a direction parallel to the base line.

The anti-reflection layer 5 is a layer to improve absorption of light and is formed on the semiconductor substrate 1 at the first surface 10a side. In more particular, the anti-reflection layer 5 is disposed on the second semiconductor layer 3 at the first surface 10a side. In addition, the anti-reflection layer 5 is formed, for example, of a silicon nitride film, a titanium oxide film, a silicon oxide film, a magnesium oxide film, an indium tin oxide film, a tin oxide film, or a zinc oxide film. Since the thickness of the anti-reflection layer 5 may be appropriately selected depending on a material to be used, a thickness that can realize no-reflection conditions with respect to appropriate incident light may be used. For example, the refractive index of the anti-reflection layer 5 may be about 1.8 to 2.3, and the thickness thereof may be about 500 to 1,200 Å. In addition, when the anti-reflection layer 5 is formed of a silicon nitride film, a passivation effect may also be obtained.

The passivation layer 8 is formed on the semiconductor substrate 1 at the second surface 10b side. The passivation layer 8 is a layer primarily including an amorphous aluminum oxide. With the structure described above, a solar cell element having a high open voltage and a good output performance can be obtained. The reason for this is construed as described below. That is, it is inferentially understood that not only a surface passivation effect but also a use of an amorphous aluminum oxide layer formed using hydrogen enhances diffusion of many hydrogen atoms contained in the aluminum oxide into the semiconductor substrate, and dangling bonds are terminated by hydrogen atoms so that surface recombination can be reduced. In addition, since the amorphous aluminum oxide layer has a negative fixed charge, the band in the vicinity of the interface is bent in a direction in which the number of minority carriers is decreased at the interface of the p-type semiconductor substrate; hence, the surface recombination of minority carriers can be further reduced.

Note that, in this embodiment, the “aluminum oxide layer 8 is primarily amorphous” indicates that the crystallization rate of the aluminum oxide layer 8 is less than 50%. The crystallization rate can be obtained from the rate of a crystalline substance occupied in an observation area, for example, by TEM (Transmission Electron Microscope) observation.

The thickness of the passivation layer 8 may be, for example, about 30 to 1,000 Å.

In addition, the aluminum oxide layer 8 has a first region 81 and a second region 82 located away from the semiconductor substrate 1 than the first region 81. In addition, the crystallization rate in the first region 81 may be lower than the crystallization rate in the second region 82. In other words, the crystallization rate of the second region 82 may be higher than the crystallization rate in the first region 81. In this manner, when the second region 82 having a higher crystallization rate is provided outside the first region 81 which is liable to be degraded by moisture and the like in the air, the first region 81 can be protected, and hence the performance as the passivation layer 8 can be maintained.

In addition, since the crystallization rate of the first region 81 is lower than that in the second region 82, when etching is performed using a hydrofluoric acid solution having 1:1000 of 46%-hydrofluoric acid:water by a volume ratio, it is exhibited a feature in which the etching rate becomes faster. In this case, it is exhibited a feature in which the etching rate of the aluminum oxide layer 8 is 3 nm/minute or more.

In addition, it is exhibited a feature in which crystallization of the second region 82 makes the negative fixed charge thereof smaller than that of the first region 81. Accordingly, in order to obtain a solar cell element having a good output performance, the thickness of the second region 82 may be decreased to one half or less of the thickness of the whole aluminum oxide layer 8.

Furthermore, in the aluminum oxide layer 8, the crystallization rate may be increased gradually or stepwise in a direction away from the semiconductor substrate 1. In this case, stress concentration in the aluminum oxide layer 8 may be reduced.

In addition, in the solar cell element 10, a silicon oxide layer 9 may be interposed between the first semiconductor layer 2 and the aluminum oxide layer 8. By this structure, since dangling bonds of the surface of the semiconductor substrate 1 at the second surface 10b side are terminated, the surface recombination of minority carriers can be reduced. Furthermore, compared to the case in which the aluminum oxide layer is directly provided on the silicon substrate, the disorder in bonding state of the aluminum oxide layer caused by influence of the silicon bonding state can be reduced. Accordingly, a high-quality aluminum oxide layer 8 having a small number of defects at the interface can be formed. As a result, the passivation effect of the aluminum oxide layer 8 is enhanced, and a solar cell element having a good output performance can be obtained. Note that, as the silicon oxide layer 9, for example, a silicon oxide film, which is formed on the surface of the semiconductor substrate 1, having a very small thickness of about 5 to 100 Å may be used.

In addition, a sheet resistance ρs of the passivation layer 8 may be set to 20 to 80Ω/□. Accordingly, since the negative fixed charge of the passivation layer 8 is large, the band in the vicinity of the interface is remarkably bent in a direction in which the number of minority carriers is decreased at the interface. As a result, the surface recombination can be further reduced, and a solar cell element having a further improved output performance can be obtained.

In addition, the sheet resistance ρs of the passivation layer 8 may be measured, for example, by a four-terminal method. In more particular, for example, the sheet resistance ρs of the passivation layer 8 can be obtained as an average of values obtained by measurement performed using a probe which is to be placed on five points, that is, the center and the corner portions, of the passivation layer 8 formed on the semiconductor substrate 1.

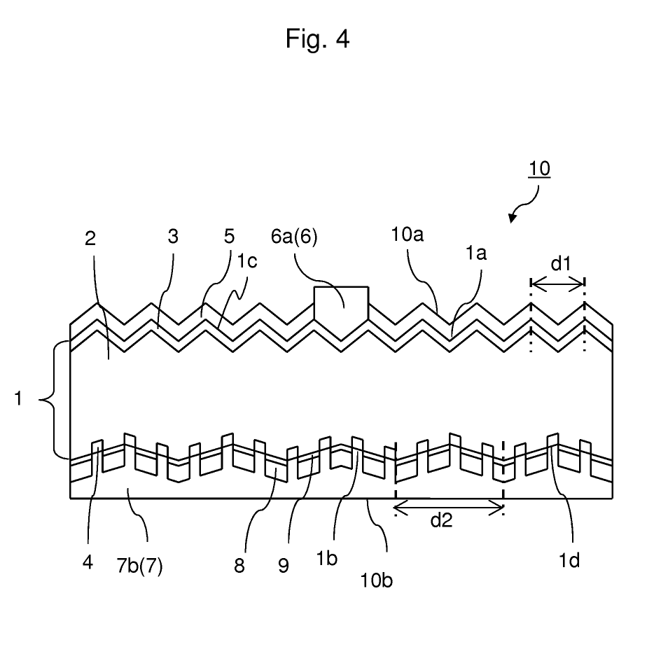

In addition, as another embodiment shown in FIG. 4, a second concavo-convex shape 1b may also be provided in the semiconductor substrate 1 at the side of a second primary surface 1d corresponding to the rear surface of the first primary surface 1c. In this case, an average distance d2 between convex portions of the second concavo-convex shape 1b of the semiconductor substrate 1 at the second primary surface 1d side may be larger than an average distance d1 between the convex portions of the first concavo-convex shape 1a at the first primary surface 1c side. In this case, the distances d1 and d2 are each regarded as an average value obtained, for example, from distances between convex portions measured at at least three positions which are arbitrarily selected.

In this manner, by further increasing the average distance d2 between the convex portions of the second concavo-convex shape 1b of the semiconductor substrate 1 at the second primary surface 1d side, the amount of light that has reflected to the semiconductor substrate 1 after passing through the semiconductor substrate 1 can be increased. In addition, since the surface area of the semiconductor substrate 1 at the second primary surface 1d side is smaller than that at the first primary surface 1c side, the surface recombination of minority carriers can be further reduced. As a result, a solar cell element having a further improved output performance can be obtained.

In addition, when a polycrystalline silicon substrate is used as the semiconductor substrate 1, although the thickness of the second region 82 tends to increase, by controlling surface contamination, a gas absorption amount, a process temperature, and the like, it is possible to reduce the thickness of the second region 82 to one half or less of the thickness of the whole aluminum oxide layer 8. Since such aluminum oxide layer 8 can obtain a sufficient negative fixed charge so as to function as the passivation layer, a polycrystalline-silicon solar cell element having a good output performance can be obtained.

Furthermore, as described below, the aluminum oxide layer 8 of this embodiment can have a good passivation effect on a polycrystalline silicon substrate. A crystalline aluminum oxide tends to grow perpendicular to a growth interface. Hence, when a substrate such as a polycrystalline silicon substrate in which grain boundaries and crystalline grains having different crystalline orientations are present is used, a growth interface of the aluminum oxide is liable to be influenced by the grain boundaries and the crystalline orientations of the crystal grains at the substrate surface, and hence the growth interface of the aluminum oxide tends to have random directions. However, since the aluminum oxide layer 8 in this embodiment is primarily amorphous, it is possible to reduce defects generated at an interference surface as a result of interference of crystal grains that has started to grow in random directions due to the influences of the grain boundaries and the crystalline orientations of the crystal grains at the surface of the polycrystalline silicon substrate. As a result, this aluminum oxide layer 8 has a good passivation effect.

The third semiconductor layer 4 is formed in the semiconductor substrate 1 at the second surface 10b side and has the same conductive type, that is, a p-type conductive type, as that of the first semiconductor layer 2. In addition, the concentration of a dopant contained in the third semiconductor layer 4 is higher than the concentration of a dopant contained in the first semiconductor layer 2. That is, a dopant element is present in the third semiconductor layer 4 at a concentration higher than the concentration of a dopant element which is doped in the first semiconductor layer 2 to exhibit one conductive type. Such third semiconductor layer 4 functions to suppress a decrease in conversion efficiency caused by recombination of minority carriers in the vicinity of the second surface 10b of the semiconductor substrate 1 and forms an internal electric field in the semiconductor substrate 1 at the second surface 10b side. The third semiconductor layer 4 may be formed, for example, by diffusing a dopant element such as boron or aluminum into the semiconductor substrate 1 at the second surface 10b side. In this case, the concentration of the dopant element contained in the third semiconductor layer 4 may be about 1×10¹⁸ to 5×10²¹ atoms/cm³. The third semiconductor layer 4 is preferably formed at a contact portion between the semiconductor substrate 1 and the second electrode 7 which will be described later.

The first electrode 6 is an electrode, which is provided on the semiconductor substrate 1 at the first surface 10a side, and includes a first output extraction electrode 6a and a plurality of linear first collector electrodes 6b as shown in FIG. 1. At least a part of the first output extraction electrode 6a intersects the first collector electrodes 6b and is electrically connected thereto. On the other hand, the first collector electrode 6b has a linear shape and also has a width of, for example, about 50 to 200 μm in its short side direction. The first output extraction electrode 6a has a width of, for example, about 1.3 to 2.5 mm in its short side direction. In addition, the width of the first collector electrode 6b in the short side direction is smaller than the width of the first output extraction electrode 6a in the short side direction. In addition, the first collector electrodes 6b are provided with intervals of about 1.5 to 3 mm therebetween. The thickness of such first electrode 6 is about 10 to 40 μm. The first electrode 6 may be formed, for example, in such a way that after a conductive paste containing silver as a primary component is applied by screen printing or the like to form a desired shape, firing is performed.

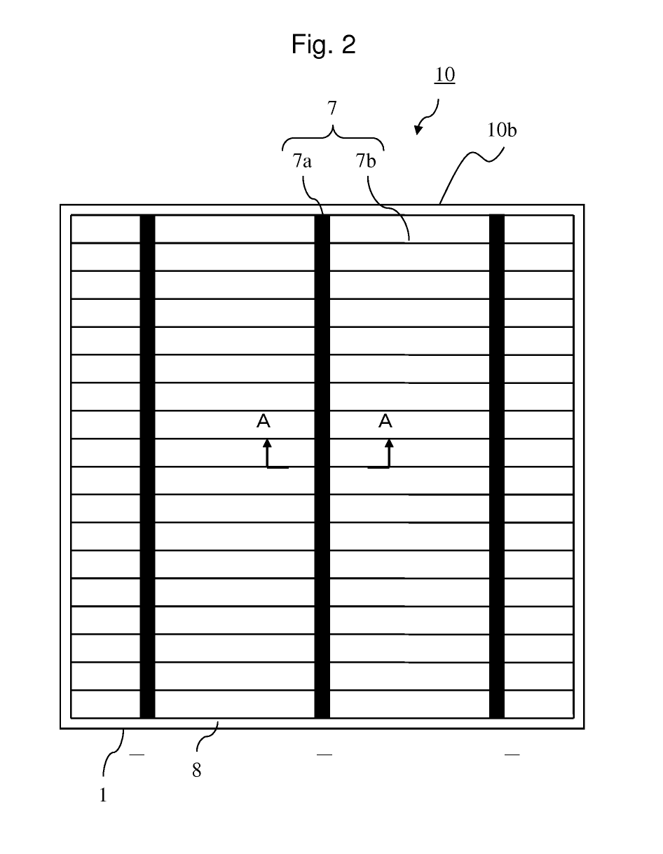

The second electrode 7 is an electrode, which is provided on the semiconductor substrate 1 at the second surface 10b side, and, for example, has a similar structure to that of the first electrode, that is, as shown in FIG. 2, includes a second output extraction electrode 7a and a plurality of linear second collector electrodes 7b. At least a part of the second output extraction electrode 7a intersects the second collector electrodes 7b and is electrically connected thereto. On the other hand, the second collector electrode 7b has a linear shape and also has a width of, for example, about 50 to 300 μm in its short side direction. The second output extraction electrode 7a has a width of, for example, about 1.3 to 3 mm in its short side direction. In addition, the width of the second collector electrode 7b in the short side direction is smaller than the width of the second output extraction electrode 7a in the short side direction. In addition, the second collector electrodes 7b are provided with intervals of about 1.5 to 3 mm therebetween. The thickness of such second electrode 7 is about 10 to 40 μm. The second electrode 7 as described above may be formed, for example, in such a way that after a conductive paste containing silver as a primary component is applied by screen printing or the like to form a desired shape, firing is performed. By making the width of the second electrode 7 in the short side direction larger than that of the first electrode 6, the series resistance of the second electrode 7 can be decreased, and the output performance of the solar cell element can be improved.

In addition, in the solar cell element 10 according to this embodiment, one or more layers other than the layers described above may be provided at both the first surface 10a side and the second surface 10b side. For example, in the solar cell element 10, an aluminum oxide layer made from a crystalline substance may be additionally provided on the aluminum oxide layer 8 at the second surface 10b side. That is, the aluminum oxide layer made from a crystalline substance may be provided between the aluminum oxide layer 8 and the second electrode 7.

### <Method for Manufacturing Solar Cell Element>

Next, one example of a method for manufacturing the solar cell element 10 will be described in detail.

First, a substrate preparation step of preparing the semiconductor substrate 1 including the first semiconductor layer (p-type semiconductor layer) 2 will be described. The semiconductor substrate 1 can be formed, for example, by an existing casting method. In addition, hereinafter, an example in which a p-type polycrystalline silicon substrate is used as the semiconductor substrate 1 will be described.

First, an ingot of polycrystalline silicon is formed, for example, by a casting method. Next, the ingot is sliced into a thickness of, for example, 250 μm or less. Subsequently, in order to clean a mechanically damaged layer and a contaminated layer of a cut surface of the semiconductor substrate 1, the surface of the semiconductor substrate 1 may be slightly etched with a solution containing NaOH, KOH, hydrofluoric acid, fluoro-nitric acid, or the like.

Next, the first concavo-convex shape 1a and the second concavo-convex shape 1b are formed in the first primary surface 1c and the second primary surface 1d, respectively, of the semiconductor substrate 1. As a method for forming each concavo-convex shape, a wet etching method using an alkaline solution containing NaOH or the like or an acid solution containing fluoro-nitric acid or the like, or a dry etching method using RIE (Reactive Ion Etching) or the like may be used to form the concavo-convex shape. Note that, in this case, by forming the first concavo-convex shape 1a at the first primary surface 1c side using a dry etching method after the second concavo-convex shape 1b is formed on the semiconductor substrate 1 at least at the second primary surface 1d side using a wet etching method, the distance d2 between the convex portions of the second concavo-convex shape 1b of the semiconductor substrate 1 at the second primary surface 1d side can be larger than the distance d1 between the convex portions of the first concavo-convex shape 1a at the first primary surface 1c side as shown in FIG. 4.

Next, a step of forming the second semiconductor layer 3 in the first primary surface 1c of the semiconductor substrate 1 having the first concavo-convex shape la formed in the above step is performed. In particular, an n-type second semiconductor layer 3 is formed in a surface layer of the semiconductor substrate 1 at the first surface 10a side having the first concavo-convex shape 1a.

This second semiconductor layer 3 may be formed, for example, by a coating thermal diffusion method in which P₂O₅ in the form of a paste is applied on the surface of the semiconductor substrate 1 and is then thermally diffused or by a vapor-phase thermal diffusion method in which a phosphorus oxychloride (POCl₃) gas is used as a diffusion source. This second semiconductor layer 3 is formed to have a depth of about 0.2 to 2 μm and a sheet resistance of about 40 to 200Ω/□. For example, in a vapor-phase thermal diffusion method, at a temperature of about 600° C. to 800° C. in an atmosphere containing a diffusion gas such as POCl₃, the semiconductor substrate 1 is processed by a heat treatment for about 5 to 30 minutes so as to form a phosphorus glass on the surface of the semiconductor substrate 1. Subsequently, by having a heat treatment at a high temperature of about 800° C. to 900° C. in an inert gas atmosphere such as argon or nitrogen for about 10 to 40 minutes, phosphorus is diffused from the phosphorus glass into the semiconductor substrate 1, and as a result, the second semiconductor layer 3 is formed in the semiconductor substrate 1 at the first surface side.

Next, in the step of forming the second semiconductor layer 3, if the second semiconductor layer 3 is also formed at the second surface 10b side, only the second semiconductor layer 3 formed at the second surface 10b side is removed by etching. Accordingly, the p-type conductive type region is exposed at the second surface 10b side. For example, the semiconductor substrate 1 at the second surface 10b side is only immersed in a fluoro-nitric acid to remove the second semiconductor layer 3 formed at the second surface 10b side. Subsequently, the phosphorus glass which is adhered onto the surface of the semiconductor substrate 1 (at the first surface 10a side) when the second semiconductor layer 3 is formed is removed by etching.

By removing the second semiconductor layer 3 formed at the second surface 10b side while the phosphorus glass is allowed to remain at the first surface 10a side, it is possible to reduce removal of or damage on the second semiconductor layer 3 at the first surface 10a side by this remaining phosphorus glass.

In addition, in the step of forming the second semiconductor layer 3, after a diffusion mask is formed at the second surface 10b side in advance, the second semiconductor layer 3 may be formed by a vapor-phase thermal diffusion method or the like, followed by removing the diffusion mask. By the process as described above, a structure similar to that described above can also be formed, and in this case, since the second semiconductor layer 3 is not formed at the second surface 10b side, the step of removing the second semiconductor layer 3 formed at the second surface 10b side is unnecessary.

In addition, the method for forming the second semiconductor layer 3 is not limited to the methods described above, and for example, by the use of a thin film technique, an n-type hydrogenated amorphous silicon film, a crystalline silicon film including a microcrystalline silicon film, or the like may be formed. Furthermore, an i-type silicon region may be formed between the first semiconductor layer 2 and the second semiconductor layer 3.

As described above, the semiconductor substrate 1 which includes the second semiconductor layer 3, that is, an n-type semiconductor layer, disposed at the first surface 10a side and the first semiconductor layer 2, that is, a p-type semiconductor layer, and which has a concavo-convex surface can be prepared.

Next, the anti-reflection layer 5 is formed on the semiconductor substrate 1 at the first surface 10a side, that is, on the second semiconductor layer 3. The anti-reflection layer 5 is formed, for example, by a PECVD (plasma enhanced chemical vapor deposition) method, a deposition method, a sputtering method, or the like. For example, when the anti-reflection layer 5 of a silicon nitride film is formed by a PECVD method, a mixed gas containing silane (SiH₄) and ammonia (NH₃) is diluted with nitrogen (N₂) and is then turned into a plasma by a glow discharge decomposition, so that the anti-reflection layer 5 is formed by deposition. In this case, an inside temperature of a film formation chamber may be set to about 500° C.

Next, the passivation layer (aluminum oxide layer) 8 composed of aluminum oxide is formed on the semiconductor substrate 1 at the second surface 10b side. The passivation layer 8 is formed, for example, using an ALD (Atomic Layer Deposition) method.

The ALD method is a method in which, for example, the following steps 1 to 4 are repeatedly performed.

Step 1: The semiconductor substrate 1 is placed in the film formation chamber, and is heated at a substrate temperature of 100° C. to 300° C. Then, an aluminum raw material such as trimethylaluminum is supplied onto the semiconductor substrate 1 for 0.5 seconds together with a carrier gas such as an argon gas or a nitrogen gas, so as to be adsorbed on the semiconductor substrate 1 at the second surface 10b side.

Step 2: Next, the inside of the film formation chamber is purged with a nitrogen gas for 1.0 second to remove the aluminum raw material present in the space of the chamber, and also, of the aluminum raw material adsorbed at the second surface 10b side, a material other than that adsorbed at an atomic layer level is also removed.

Step 3: Next, an oxidizing agent such as an ozone gas is supplied into the film formation chamber for 4.0 seconds to remove CH₃ which is an alkyl group of trimethylaluminum used as the aluminum raw material, and also, a dangling bond of aluminum is oxidized so as to form an atomic layer of aluminum oxide at the second surface 10b side.

Step 4: Next, the inside of the film formation chamber is purged with a nitrogen gas for 1.5 seconds to remove the oxidizing agent present in the space of the chamber, and also, materials such as an oxidizing agent having no contribution to the reaction other than the aluminum oxide at an atomic layer level formed at the second surface 10b side are removed.

In addition, when a process including the above steps 1 to 4 is repeated, an aluminum oxide layer 8 that has a predetermined thickness and that is primarily amorphous can be formed. In addition, when hydrogen is contained in the oxidizing agent used in the above step 3, hydrogen is likely to be contained in the aluminum oxide layer 8, and hence a hydrogen passivation effect can be enhanced. In addition, the passivation layer 8 composed of the aluminum oxide layer may also be formed on side surfaces of the semiconductor substrate 1.

In addition, when the temperature of the semiconductor substrate 1 is increased from the step 1 to the step 4, the aluminum oxide layer 8 may be formed to include the first region 81 and the second region 82 that is located away from the semiconductor substrate 1 than the first region 81, and the crystallization rate of the first region 81 may be set to be lower than that of the second region 82. For example, for the film formation, when the temperature of the semiconductor substrate 1 is set to 100° C. to 200° C. in the first region 81 and is set to about 300° C. in the second region 82, an aluminum oxide layer 8 having a desired crystallization rate may be formed.

In addition, when a film formation process including the steps 1 to 4 is regarded as on cycle, when the temperature of the semiconductor substrate 1 is increased gradually or stepwise in every cycle, the aluminum oxide layer 8 may be formed so that the crystallization rate thereof is increased gradually or stepwise in a direction away from the semiconductor substrate 1.

Next, the first electrode 6 (first output extraction electrode 6a and first collector electrodes 6b) and the second electrode 7 (first layer 7a and second layer 7b) are formed as described below.

First, the first electrode 6 will be described. The first electrode 6 is formed using a conductive paste containing, for example, a metal powder composed of silver (Ag) or the like, an organic vehicle and a glass frit. This conductive paste is applied onto the semiconductor substrate 1 at the first surface 10a side and is then fired at a maximum temperature of 600° C. to 800° C. for about several tens of seconds to several tens of minutes, thereby forming the first electrode 6. As a method for applying the conductive paste, for example, a screen printing method may be used. After this application, a solvent may be evaporated at a predetermined temperature for drying. In addition, although the first electrode 6 has the first output extraction electrode 6a and the first collector electrodes 6b, when screen printing is used, the first extraction electrode 6a and the first collector electrodes 6b may be formed by one step.

Next, the third semiconductor layer 4 will be described. First, an aluminum paste containing a glass frit is directly applied on a predetermined region of the passivation layer 8. Subsequently, by a fire-through method in which a high-temperature heat treatment is performed at a maximum temperature of 600° C. to 800° C., the paste component thus applied breaks through the passivation layer 8 and forms the third semiconductor layer 4 in the semiconductor substrate 1 at the second surface 10b side, and an aluminum layer (not shown) is formed on the third semiconductor layer 4. As a region of forming this aluminum layer, for example, in a region of the second surface 10b in which the second electrode 7 is to be formed, dot shapes may be formed with intervals of 200 μm to 1 mm therebetween. In addition, the aluminum layer formed on the third semiconductor layer 4 may be removed before the second electrode 7 is formed or may be used as the second electrode 7 without performing any additional modification.

Next, the second electrode 7 will be described. The second electrode 7 is formed using a conductive paste containing, for example, a metal powder composed of silver (Ag) or the like, an organic vehicle, and a glass frit. This conductive paste is applied onto the second surface 10b of the semiconductor substrate 1 and is then fired at a maximum temperature of 500° C. to 700° C. for about several tens of seconds to several tens of minutes, thereby forming the second electrode 7. As an application method, for example, a screen printing method may be used. After this application, as in the case of the formation of the first electrode 6, a solvent may be evaporated at a predetermined temperature for drying. Note that, as in the case of the formation of the first electrode 6, although the formation of the second electrode 7 includes the second output extraction electrode 7a and the second collector electrodes 7b, when screen printing is used, the second output extraction electrode 7a and the second collector electrodes 7b may be formed by one step.

Although the embodiment in which the first electrode 6 and the second electrode 7 are formed by printing and firing methods is described by way of example, those electrodes may also be formed by using a thin-film formation method such as a deposition method and a sputtering method, or a plating method.

In addition, in each step performed after the above-mentioned step of forming the passivation layer 8, the maximum temperature of the heat treatment in each step may be set to 800° C. or less. Accordingly, since the crystallization rate of the aluminum oxide layer 8 that is composed of primarily amorphous is decreased, while the properties derived from the non-crystallinity of the above aluminum oxide layer 8 are maintained, the hydrogen passivation effect can be enhanced. For example, in each step performed after the step of forming the passivation layer 8, a thermal history in a heat treatment performed at 300° C. to 500° C. may be set to 5 to 30 minutes. In particular, when polycrystalline silicon is used as the semiconductor substrate as in this embodiment, under the conditions described above, the crystallization rate of aluminum oxide of the aluminum oxide layer 8 can be decreased.

As described above, the solar cell element 10 can be manufactured.

### MODIFIED EXAMPLES

The present invention is not limited to the above embodiment, and various modifications and changes thereof may be performed.

For example, before the passivation layer 8 is formed, the third semiconductor layer 4 may be formed. In this case, before the step of forming the passivation layer 8, boron or aluminum may be diffused in a predetermined region of the second surface 10b. By a thermal diffusion method using boron tribromide (BBr₃) as a diffusion source, boron may be diffused by heating the semiconductor substrate 1 to a temperature of about 800° C. to 1,100° C. In addition, as the third semiconductor layer 4, a p-type hydrogenated amorphous silicon film, a crystalline silicon film including a microcrystalline silicon film, or the like, which is formed, for example, by a thin film technique, may also be used. Furthermore, an i-type silicon region may also be formed between the semiconductor substrate 1 and the third semiconductor layer 4.

In addition, the anti-reflection layer 5 and the passivation layer 8 may be formed in the order opposite to that described above.

In addition, before the anti-reflection layer 5 and the passivation layer 8 are formed, the semiconductor substrate 1 may be cleaned. As a cleaning step, for example, there may be used a hydrofluoric acid treatment, RCA cleaning (developed by RCA Corp. in USA, a cleaning method using high-temperature and high-concentration sulfuric acid/hydrogen peroxide water, diluted hydrofluoric acid (room temperature), ammonium water/hydrogen peroxide water, or hydrochloric acid/hydrogen peroxide water, or the like) and a hydrofluoric acid treatment performed after this cleaning, or a SPM (Sulfuric Acid/Hydrogen Peroxide/Water Mixture) cleaning and a hydrofluoric acid treatment, or the like, performed after this cleaning.

In addition, before the anti-reflection layer 5 and the passivation layer 8 are formed, the silicon oxide layer 9 may also be formed. This silicon oxide layer 9 may be formed as a layer having a thickness of about 5 to 100 Å and located on the semiconductor substrate 1 at the second surface 10b side by treating the semiconductor substrate 1 with a nitric acid solution or a nitric acid vapor using a nitric acid oxidation method after a native oxide film formed on the semiconductor substrate 1 is removed by a hydrofluoric acid treatment or the like. As described above, when a thin silicon oxide layer 9 is formed at the second surface 10b side, the passivation effect can be further enhanced. In more particular, when the semiconductor substrate 1 is immersed in a heated nitric acid solution at a concentration of 60 percent by mass or more or is maintained in a nitric acid vapor generated by heating a nitric acid solution at a concentration of 60 percent by mass or more to boiling, the silicon oxide layer 9 can be formed on the surface of the semiconductor substrate 1. Note that the temperature of the nitric acid solution used in this case may be set, for example, in a range of from 100° C. to a temperature slightly lower than the boiling point. In addition, the treatment time may be appropriately selected such that the silicon oxide layer 9 has a predetermined thickness. Since the nitric acid oxidation method has a significantly lower treatment temperature than that of a thermal oxidation method and can be performed by a wet treatment, when the nitric oxidation method is performed continuously after the cleaning step, the passivation layer 8 may be formed in the state in which the contamination of the surface is reduced. Hence, even when the polycrystalline silicon substrate 1 is used, an aluminum oxide layer which is primarily amorphous may be formed.

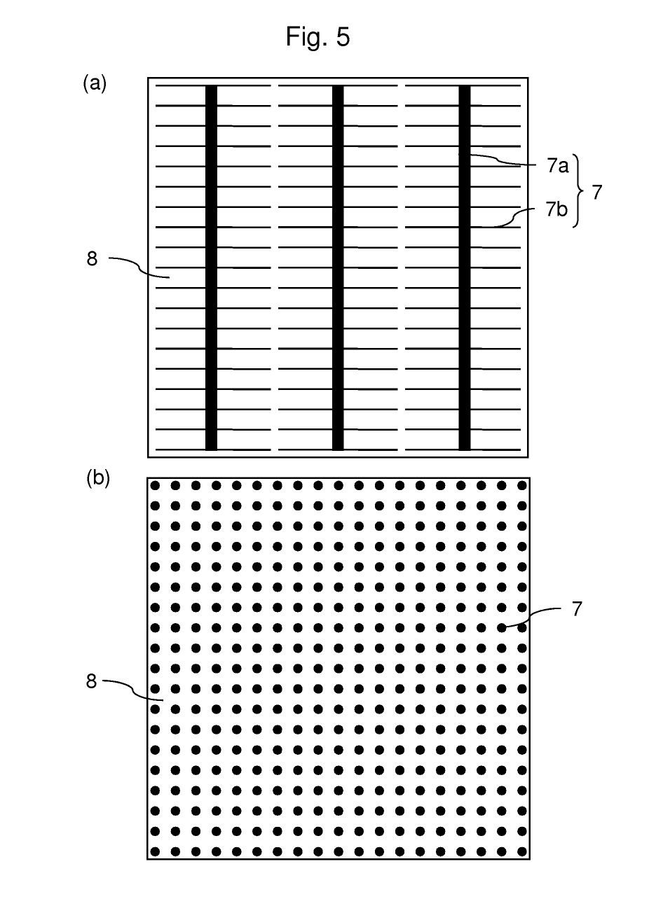

In addition, the shape of the second electrode 7 is not limited to the lattice shape described above, and as shown in FIG. 5(a), the second electrode 7 may be formed in such a way that at least part of each of the second collector electrodes 7b is removed, and separated second collector electrodes 7b are connected to the second output extraction electrode 7a, respectively. In addition, as shown in FIG. 5(b), the second electrode 7 may be formed in dot shapes. In this case, the second electrodes 7 formed in the dot shapes may be connected with each other using a conductive sheet or the like. In addition, as a method for connecting the conductive sheet and the second electrodes 7 each having the dot shape, a conductive adhesive or a solder paste may be used. In addition, the second electrode 7 may be formed almost over the entire surface of the semiconductor substrate 1, and in this case, of light passing through the semiconductor substrate 1 and the passivation layer 8, the amount of light that is again reflected to the semiconductor substrate 1 can be increased by the second electrode 7. In this case, a metal having a high reflectance such as silver may be used for the second electrode 7.

In addition, in any step performed after the step of forming the passivation layer 8, when an annealing treatment using a gas containing hydrogen is performed, a recombination rate of minority carriers at the rear surface (second primary surface 1d) of the semiconductor substrate 1 can be further decreased.

In addition, when a solar cell element using a polycrystalline silicon substrate having an n-type conductivity as the semiconductor substrate 1, since the second semiconductor layer 3 has a p-type conductivity, a passivation layer primarily composed of the amorphous aluminum oxide layer 8 is formed on the semiconductor substrate 1 at the first surface 10a side, the effect of this embodiment described above can be expected.

### <Solar Cell Module>

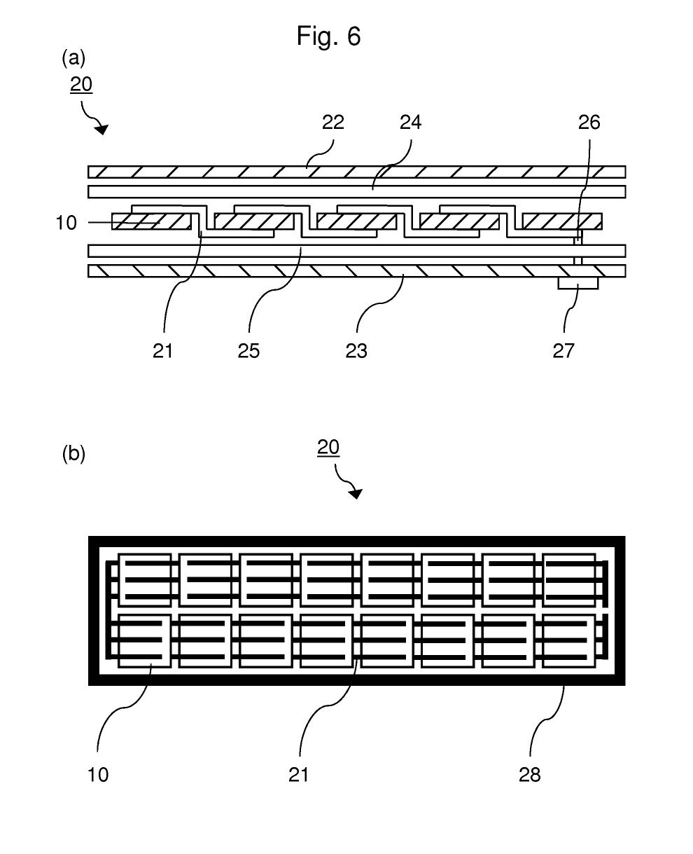

A solar cell module 20 according to this embodiment will be described in detail with reference to FIGS. 6(a) and 6(b). The solar cell module 20 includes one or more solar cell elements 10 of the embodiment described above. In particular, in the solar cell module 20, the solar cell elements 10 are electrically connected to each other.

When a single solar cell element 10 has a low electrical output, the solar cell elements 10 are connected to each other in series or in parallel to form the solar cell module 20. When the solar cell modules 20 described above are used in combination, a practical electrical output can be obtained.

As shown in FIG. 6(a), the solar cell module 20 primarily includes, for example, a transparent member 22 such as a glass; a front-side filling member 24 formed from a transparent EVA or the like; the solar cell elements 10; wire members 21 connecting the solar cell elements 10; a rear-side filling member 25 formed from EVA or the like; and a rear-surface protective member 23 which has a single-layer or a multilayer structure formed from a material such as a poly(ethylene terephthalate) (PET) or a poly(vinyl fluoride) (PVF) resin.

Solar cell elements 10 located adjacent to each other are electrically connected in series in such a way that the first electrode 6 of one solar cell element 10 is connected to the second electrode 7 of the other solar cell element 10 with the wire member 21.

As the wire member 21, for example, used is a member of which the entire surface of a copper foil having a thickness of about 0.1 to 0.2 mm and a width of about 2 mm is coated with a solder material.

In addition, among the solar cell elements 10 which are connected to each other in series, each one end of electrodes of one terminal of a first solar cell element 10 and one terminal of a last solar cell element 10 is connected to a terminal box 27 functioning as an output extraction portion with an output extraction wire 26. In addition, although not shown in FIG. 6(a), as shown in FIG. 6(b), the solar cell module 20 may include a frame 28 composed of aluminum or the like.

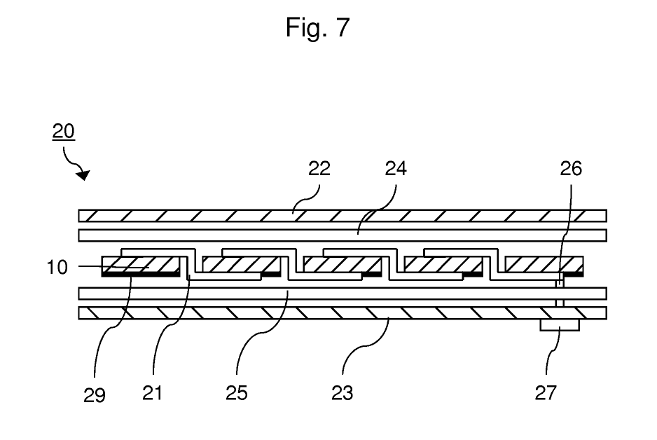

In addition, in the solar cell module 20, when a reflection sheet 29 having a high reflectance is further provided on the solar cell element 10 at the second surface 10b side as shown in FIG. 7, a high performance rear-surface reflection structure can be realized.

Since the solar cell module 20 according to this embodiment includes the solar cell elements 10 each having the passivation layer described above, the solar cell module 20 has a good output performance.

Heretofore, although several embodiments of the present invention have been disclosed by way of examples, the present invention is not limited to the above embodiments, and it is to be construed that the embodiments may be arbitrarily changed without departing from the scope of the present invention.

### EXAMPLES

Hereinafter, examples will be described. In addition, the structure of a solar cell element will be described with primary reference to FIG. 3.

Solar cell elements according to Examples 1 to 3 were each formed as described below. First, a semiconductor substrate 1 having a p-type first semiconductor layer 2 was prepared as described below. After an ingot of polycrystalline silicon doped with boron was formed by a casting method, a thin plate having a predetermined shape was obtained by slicing the ingot using a wire saw machine. As described above, a semiconductor substrate 1 having a thickness of about 220 μm, a square shape having one side length of 156 mm in plan view, and a specific resistance of 1.0 Ω·cm was prepared.

Next, in a first primary surface 1c of the semiconductor substrate 1, a first concavo-convex shape 1a was formed by a RIE method so that the height of the convex portion was about 0.5 μm, the width thereof was about 1 μm, and a distance d1 between the convex portions was about 1 μm.

Next, a second semiconductor layer 3 was formed on the first primary surface 1c of the semiconductor substrate 1. The second semiconductor layer 3 was formed by a vapor-phase thermal diffusion method using a POCl₃ gas as a diffusion source to have a thickness of about 1 μm and a sheet resistance of about 80 Ω/□.

Next, an anti-reflection layer 5 was formed on the second semiconductor layer 3 by a PECVD method. That is, a mixed gas of SiH₄ and NH₃ was diluted with N₂ in a film formation chamber and was then turned into a plasma by glow discharge decomposition, so that the anti-reflection layer 5 was formed by deposition. In this case, the temperature in the film formation chamber was set to about 500° C.

Next, a passivation layer 8 of an aluminum oxide layer was formed primarily by an ALD method on the semiconductor substrate 1 at the second primary surface 1d side.

### Example 1

The semiconductor substrate 1 was placed in the film formation chamber and was heated so that the surface temperature of the semiconductor substrate 1 was about 180° C. Next, a trimethylaluminum gas was supplied on the semiconductor substrate 1 with a carrier gas formed of a nitrogen gas for 0.5 seconds, so that an aluminum raw material was adsorbed on the semiconductor substrate 1 at the second primary surface 1d side (step 1). Next, the inside of the film formation chamber was purged with a nitrogen gas for 1.0 second, so that the aluminum raw material in the space of the chamber was removed, and also, of the aluminum raw material adsorbed at the second surface 10b side, a material other than that adsorbed at an atomic layer level was also removed (step 2). Subsequently, an oxidizing agent formed from an ozone gas was supplied with a carrier gas formed of a nitrogen gas into the film formation chamber for 4.0 seconds to remove CH₃ which was an alkyl group of trimethylaluminum used as the aluminum raw material, and also, a dangling bond of aluminum was oxidized so as to form an atomic layer of aluminum oxide at the second primary surface 1d side (step 3). Next, the inside of the film formation chamber was purged with a nitrogen gas for 1.5 seconds to remove the oxidizing agent in the space of the chamber, and also, materials, such as an oxidizing agent having no contribution to the reaction, other than the aluminum oxide at an atomic layer level adsorbed at the second primary surface 1d side were removed (step 4). In addition, when the steps 1 to 4 described above were repeatedly performed, an aluminum oxide layer 8, which is primarily amorphous, having a thickness of 30 nm was formed. In this case, by TEM observation, it was confirmed that no crystalline substance was present in the aluminum oxide layer 8.

### Example 2

After a first region 81 of an amorphous aluminum oxide layer having a thickness of 20 nm was formed under the same conditions as those in Example 1, the substrate temperature was set to 280° C., and under the same conditions as those of Example 1, a second region 82 of a crystalline aluminum oxide layer having a thickness of 10 nm was formed. It was confirmed by TEM observation that 80% of a crystalline substance was present in the second region 82.

### Example 3

Before the passivation layer 8 was formed, a silicon oxide layer 9 was formed by a nitric acid oxidation method. In this nitric acid oxidation method, after a native oxide film formed on the semiconductor substrate 1 was removed by a hydrofluoric acid treatment, the semiconductor substrate 1 was immersed in a nitric acid solution heated to 120° C. and having a concentration of 68 percent by mass, so that a silicon oxide layer 9 having a thickness of 5 nm was formed on the surface of the semiconductor substrate 1. Subsequently, by the same method as that of Example 1, a passivation layer 8 having a thickness of 30 nm was formed. In addition, it was confirmed by TEM observation that no crystalline substance was present in the aluminum oxide layer 8.

### Comparative Example 1

Under the same conditions as those in which the second region 82 was formed in Example 2, a crystalline passivation layer 8 having a thickness of 30 nm was formed. It was confirmed by TEM observation that 80% of a crystalline substance was present in the passivation layer.

Next, a first electrode 6 (first output extraction electrode 6a and first collector electrodes 6b) and a second electrode 7 (first layer 7a and second layers 7b) were formed as described below. First, the first electrode 6 was formed. The first electrode 6 was formed in such a way that a conductive paste containing a metal powder formed from Ag or the like, an organic vehicle, and a glass frit was applied on a first surface 10a of the semiconductor substrate 1 by a screen printing method, and firing was then performed at a maximum temperature of 750° C. for about several tens of seconds to several tens of minutes.

The third semiconductor layer 4 was formed as described below. First, an aluminum paste containing a glass frit was directly applied on a predetermined region of the passivation layer 8. Subsequently, by a fire-through method in which a high-temperature heat treatment was performed at a maximum temperature of 750° C., the paste component thus applied broke through the passivation layer 8, so that the third semiconductor layer 4 was formed in the semiconductor substrate 1 at the second surface 10b side. In addition, an aluminum layer was formed on the third semiconductor layer 4. In a region of the second surface 10b in which the second electrode 7 was to be formed, a region of forming this aluminum layer was formed to include dot shapes.

The second electrode 7 was formed as described below. The second electrode 7 was formed using a conductive paste containing a metal powder formed from Ag, an organic vehicle, and a glass frit. This conductive paste was applied onto the second surface 10b of the semiconductor substrate 1 and was then fired at a maximum temperature of about 750° C. for about several tens of seconds to several tens of minutes, so that the second electrode 7 was formed. As this application method, a screen printing method was used.

As described above, the solar cell elements 10 of Examples 1 to 3 and Comparative Example 1 were formed.

A short-circuit current lsc, an open voltage Voc, a fill factor FF, and a photoelectric conversion efficiency of each of those solar cell elements were measured. In addition, the measurement of those properties was performed in accordance with JIS C 8913 under light irradiation conditions at an AM (Air Mass) of 1.5 and an irradiation of 100 mW/cm².

The measurement results are shown in Table 1.

TABLE 1

| | | | | photoelectric |
|---|---|---|---|---|
| | Isc | Voc | FF | conversion |
| | [mA] | [V] | [—] | efficiency [%] |
| Example 1 | 8639 | 0.624 | 0.771 | 17.08 |
| Example 2 | 8615 | 0.623 | 0.769 | 16.96 |
| Example 3 | 8688 | 0.625 | 0.770 | 17.18 |
| Comparative | 8518 | 0.617 | 0.770 | 16.63 |
| Example 1 | | | | |

As shown in Table 1, the solar cell elements of Examples 1 to 3 all showed higher short-circuit lsc, open voltage Voc, and photoelectric conversion efficiency than those of the solar cell element of Comparative Example 1, and hence it was confirmed that a solar cell element having a good output performance could be provided. In addition, it was also confirmed that the solar cell elements of Examples 1 and 2 each also had a high fill factor FF. Furthermore, it was also confirmed that the solar cell element of Example 3 had the highest conversion efficiency.

In addition, a high-temperature and high-humidity test was performed in accordance with JIS C 8917, and the rate of degradation in photoelectric conversion efficiency was evaluated from the results obtained before and after this test. As a result, it was confirmed that since the rate of degradation in Example 2 was smallest as compared to those of Examples 1 and 3, the solar cell element of Example 2 had the highest reliability.

Furthermore, in Examples 1 to 3, after the second concavo-convex shape 1b was formed in the semiconductor substrate 1 at the second primary surface 1d side using a wet etching method with a fluoro-nitric acid solution, the first concavo-convex shape 1a was formed in the semiconductor substrate 1 at the first primary surface 1c side using a RIE method so that the distance d2 (about 10 μm) between the convex portions of the second concavo-convex shape 1b at the second primary surface 1d side was larger than the distance d1 (about 1 μm) between the convex portions of the first concavo-convex shape 1a at the first primary surface 1c side. Subsequently, various properties of the solar cell formed as described above were measured, and it was confirmed that the photoelectric conversion efficiency of this solar cell element was higher than that of a solar cell element in which the second concavo-convex shape 1b was not formed at the second primary surface 1d side.

### DESCRIPTIONS OF THE REFERENCE NUMERALS

1: semiconductor substrate (silicon substrate)
1a: first concavo-convex shape
1b: second concavo-convex shape
1c: first primary surface
1d: second primary surface
2: first semiconductor layer (p-type semiconductor layer)
3: second semiconductor layer (opposite conductive type semiconductor layer)
4: third semiconductor layer
5: anti-reflection layer
6: first electrode
6a: first output extraction electrode
6b: first collector electrode
7: second electrode
7a: first layer
7b: second layer
8: passivation layer (aluminum oxide layer)
81: first region
82: second region
9: silicon oxide layer
10: solar cell element
10a: first surface
10b: second surface
20: solar cell module

1. A solar cell element comprising
a polycrystalline silicon substrate comprising a p-type semiconductor layer located at a surface thereof; and
an aluminum oxide layer located on the p-type semiconductor layer,
wherein the aluminum oxide layer is primarily amorphous.

2. The solar cell element according to claim 1, wherein
the aluminum oxide layer comprises a first region and a second region,
the second region is located on the first region, and
a crystallization rate of the first region is lower than a crystallization rate of the second region.

3. The solar cell element according to claim 2, wherein the crystallization rate of the aluminum oxide layer is increased gradually or stepwise in a direction away from the silicon substrate.

4. The solar cell element according to claim 1, further comprising a silicon oxide layer between the p-type semiconductor layer and the aluminum oxide layer.

5. The solar cell element according to claim 1, wherein a sheet resistance ρs of the aluminum layer is 20 to 80 Ω/□.

6. The solar cell element according to claim 1, wherein
the silicon substrate comprises:
a first primary surface having a first concavo-convex shape; and
a second primary surface; opposed to the first primary surface; comprising the aluminum oxide layer and having a second concavo-convex shape, and
an average distance between convex portions of the second concavo-convex shape is larger than an average distance between convex portions of the first concavo-convex shape.

7. A solar cell module comprising:
a solar cell element according to claim 1.
